(19) United States
(12) Patent Application Publication
(10) Pub. No.: US 2026/0144103 A1
(43) Pub. Date: May 21, 2026

(54) POWER MODULE

(71) Applicants: HYUNDAI MOTOR COMPANY, Seoul (KR); KIA CORPORATION, Seoul (KR)

(72) Inventors: Han Jin Do, Hwaseong-si (KR); Dong Hwan Lee, Hwaseong-si (KR); Jin Myeong Yang, Hwaseong-si (KR); Sung Won Park, Hwaseong-si (KR)

(73) Assignees: HYUNDAI MOTOR COMPANY, Seoul (KR); KIA CORPORATION, Seoul (KR)

(21) Appl. No.: 19/207,293

(22) Filed: May 13, 2025

(30) Foreign Application Priority Data
Nov. 20, 2024 (KR) 10-2024-0166367

(51) Int. Cl. H01L 23/538; H01L 23/00; H01L 23/31; H01L 25/065

(52) U.S. Cl. CPC H10W 70/65; H10W 70/611; H10W 74/111; H10W 72/884; H10W 90/00; H10W 90/734; H10W 90/736; H10W 90/754

(57) ABSTRACT

A power module is provided. The power module includes a substrate on which at least one chip is mounted, a power lead connected to the substrate to supply power to the chip or output power converted by the chip, a metal layer electrically connected to the chip and the power lead to form a current loop, and a molded portion surrounding at least a portion of an outer surface of the substrate, the power lead, and the metal layer so that the chip is embedded therein.

### CROSS-REFERENCE TO RELATED APPLICATION(S)

This application claims the benefit of priority to Korean Patent Application No. 10-2024-0166367 filed on Nov. 20, 2024, in the Korean Intellectual Property Office, the disclosure of which is incorporated herein by reference in its entirety.

### TECHNICAL FIELD

The present disclosure relates to a power module.

### BACKGROUND

Recently, as interest in the environment has increased, eco-friendly vehicles equipped with electric motors as a power source has increased. Eco-friendly vehicles are also referred to as electrified vehicles, and representative examples include electric vehicles (EVs) and hybrid electric vehicles (HEVs). Inverters have been used as core components for power control affecting the performance and efficiency of such vehicles.

An inverter is a device converting direct current (DC) power into alternating current (AC) power and may drive an electric motor upon receiving power from a high-voltage battery. The inverter includes a power module as a core component. The power module processes high voltage and current to perform power conversion.

Power modules may be classified into single-sided cooling power modules and double-sided cooling power modules depending on a cooling method. Single-sided cooling power modules may be provided with a current loop formed on a lower substrate, and a separate cooling device connected to a portion of the lower substrate exposed externally to perform cooling.

### SUMMARY

An aspect of the present disclosure is to provide a power module which is useful in miniaturization and has improved electrical characteristics.

Another aspect of the present disclosure is to provide a power module that may reduce the manufacturing cost.

According to an aspect of the present disclosure, a power module includes a substrate on which at least one chip is mounted, a power lead connected to the substrate to supply power to the chip or output power converted by the chip, a metal layer electrically connected to the chip and the power lead to form a current loop, and a molded portion surrounding at least a portion of an outer surface of the substrate, the power lead, and the metal layer so that the chip is embedded therein.

According to another aspect of the present disclosure, a power module includes a substrate on which a chip is mounted, a power lead connected to the substrate to supply power to the chip, a metal layer electrically connected to the chip and the power lead to form a current loop and having at least one through-hole formed therein, and a molded portion provided to surround at least a portion of an outer surface of the substrate, the power lead, and the metal layer so that the chip is embedded therein.

### BRIEF DESCRIPTION OF DRAWINGS

The above and other aspects, features, and advantages of the present disclosure will be understood from the following detailed description, taken in conjunction with the accompanying drawings.

FIG. 1 is a schematic cross-sectional view of a power module according to an embodiment of the present disclosure.

FIG. 2 is a schematic perspective view of a metal layer provided in a power module according to an embodiment of the present disclosure.

FIG. 3 is a schematic cross-sectional view of a power module according to another embodiment of the present disclosure.

FIG. 4 is a schematic cross-sectional view of a power module according to another embodiment of the present disclosure.

FIG. 5 is a schematic perspective view of a metal layer provided in a power module according to another embodiment of the present disclosure.

FIG. 6 is a schematic cross-sectional view of a power module according to another embodiment of the present disclosure.

FIG. 7 is a schematic cross-sectional view of a power module according to another embodiment of the present disclosure.

FIG. 8 is a schematic perspective view of a metal layer provided in a power module according to another embodiment of the present disclosure.

FIG. 9 is a schematic cross-sectional view of a power module according to another embodiment of the present disclosure.

FIG. 10 is a schematic perspective view of a metal layer provided in a power module according to another embodiment of the present disclosure.

### DETAILED DESCRIPTION

While the present disclosure may be modified in various ways and take on various alternative forms, specific embodiments thereof are shown in the drawings and described in detail herein. However, there is no intent to limit the present disclosure to the particular forms disclosed, but rather, the present disclosure is intended to cover modifications, equivalents, and alternatives falling within the spirit and scope of the present disclosure.

It will be understood that, although the terms “first,” “second,” and/or the like may be used herein to describe various elements, these elements may not be limited by these terms. These terms are used to distinguish one element from another. For example, a first element could be termed a second element, and a second element could similarly be termed a first element without departing from the scope of the present disclosure. As used herein, the term “and/or” includes combinations of one or more of the associated listed items.

The terms, such as “unit,” “part,” “portion,” and/or the like may be used to describe various components, but the components may not be limited by these terms. The above terms may refer to physically/visually distinct components, and to functions or components of a portion even if the corresponding portion is not (e.g., clearly) divided.

The terms used herein to describe embodiments of the present disclosure is not intended to limit the scope of the present disclosure. The articles “a,” and “an” are singular in that they have a single referent, however the use of the singular form in the present document may not preclude the presence of more than one referent. In other words, elements of the present disclosure referred to in the singular may be one or more, unless the context indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless provided in a different way, the terms used herein including technical and scientific terms have the same meanings as understood by those skilled in the art to which the present disclosure pertains. Such terms as generally used dictionaries may be construed to have the same meanings as those of the contexts of the related art, and unless provided in the application, they may not be construed to have ideally or excessively formal meanings.

In the description below, terms “upper,” “lower,” “upper surface,” “lower surface,” “bottom,” and/or the like used in relation to directions are generally described based on the illustration in the drawing. Hereinafter, embodiments of the present disclosure will be described with reference to the accompanying drawings.

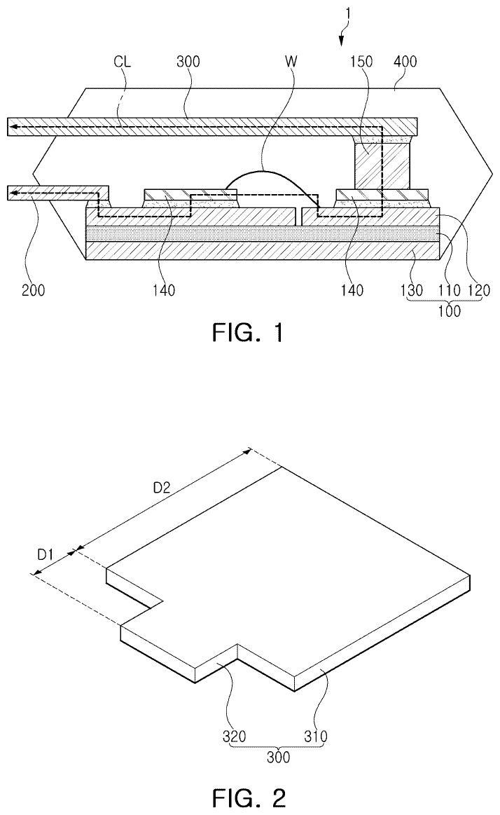

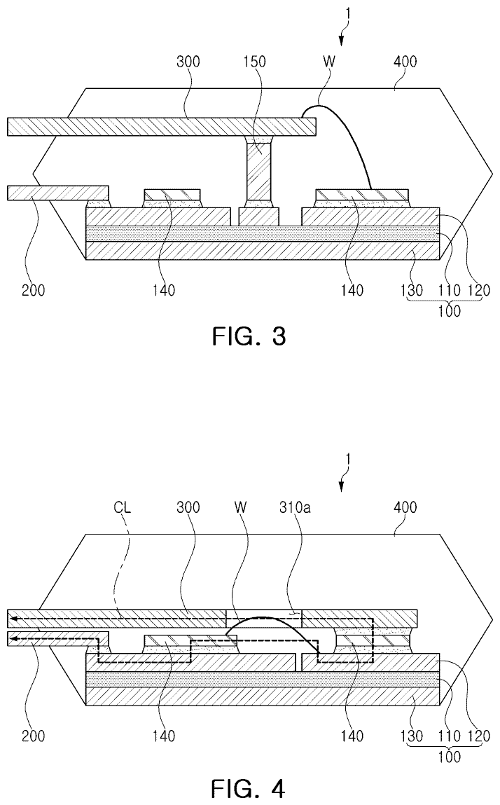

FIG. 1 is a schematic cross-sectional view of a power module according to an embodiment of the present disclosure, FIG. 2 is a schematic perspective view of a metal layer provided in a power module according to an embodiment of the present disclosure, and FIG. 3 is a schematic cross-sectional view of a power module according to another embodiment of the present disclosure.

Referring to FIG. 1, a power module 1 according to an embodiment of the present disclosure may include a substrate 100, a power lead 200, a metal layer 300, and a molded portion 400.

The power module 1 according to an embodiment of the present disclosure may correspond to an insulated power module including an insulating layer on the substrate 100 or a non-insulated power module (e.g., not including an insulating layer). The insulated power module and the non-insulated power module differ in whether an insulating layer is included inside the substrate on which a chip is mounted, and the other components may be the same. Hereinafter, an insulated power module including an insulating layer on the substrate 100 will be described as an example.

The substrate 100 may include an insulating layer 110, an internal metal layer 120, and an external metal layer 130. The insulating layer 110 may include a polymer resin. The insulating layer 110 may be provided in a plate shape, for example. The internal metal layer 120 may be provided on an upper surface of the insulating layer 110. A plurality of circuit lines may be provided on the internal metal layer 120. The circuit lines of the internal metal layer 120 may provide circuit patterns. The circuit lines of the internal metal layer 120 may be connected to the power lead 200 or a signal lead (not shown). The internal metal layer 120 may be formed of a conductor having high electrical conductivity. For example, the internal metal layer 120 may include copper (Cu). The external metal layer 130 may be provided on a lower surface of the insulating layer 110. At least a portion of the external metal layer 130 may be exposed to the outer surface of the molded portion 400. A separate cooling channel (not shown) may be connected to the externally exposed portion of the external metal layer 130. When a chip 140 mounted on the substrate 100 operates, heat may be generated, and the heat generated by the chip 140 may be transferred to the external metal layer 130 of the substrate 100. The heat generated by the chip 140 may be released externally through the external metal layer 130. The power module 1 may correspond to a single-sided cooling power module, for example.

At least one chip 140 may be mounted on the substrate 100. The chip 140 may be electrically connected to the internal metal layer 120 of the substrate 100. The chip 140 may include at least one of an insulated gate bipolar transistor (IGBT), a compound semiconductor (SIC), a shunt circuit, a silicon controlled rectifier (SCR), a MOSFET, a power transistor, a MOS transistor, a power rectifier, a power regulator, or a diode. When the chip 140 is provided in plural, at least some of the plurality of chips 140 may be electrically connected to the metal layer 300.

A spacer 150 may be provided between the metal layer 300 and the chip 140. The spacer 150 may support the metal layer 300 so that the metal layer 300 may be disposed above the substrate 100. The spacer 150 may separate the metal layer 300 from the substrate 100 and the chip 140. The spacer 150 may electrically connect the metal layer 300 to the chip 140 or the metal layer 300 to the substrate 100. Further, the spacer 150 may be provided as a conductive block. The conductive block may refer to a rigid body that conducts electricity, such as a copper block or a PCB.

The power lead 200 may be connected to the substrate 100. The power lead 200 may be provided to supply power to the chip 140 mounted on the substrate 100 or to output power converted by the chip 140. The power lead 200 may include, for example, an input terminal connected to a high-voltage battery to receive direct current (DC) and supply DC to the chip 140 and an output terminal outputting an alternating current (AC) converted by the chip 140. The input terminal may correspond to at least one of a positive terminal and a negative terminal.

The power lead 200 may correspond to one of the negative terminal, the positive terminal, and the output terminal. Meanwhile, although not shown in the drawing, a signal lead for transmitting a control signal to the chip 140 may be connected to the substrate 100.

The metal layer 300 may be spaced apart from the substrate 100. The metal layer 300 may be electrically connected to the chip 140 and the power lead 200 to form a current loop (CL). Here, the current loop CL may refer to a path through which current input from an external source passes through each component inside the power module 1 and is output externally.

The metal layer 300 may be formed of a conductive component, such as low temperature co-fired ceramic (LTCC), printed circuit board (PCB), or metal. In addition to the substrate 100, the metal layer 300 may serve as an additional current path to improve the electrical characteristics of the power module 1. In other words, the metal layer 300 may provide an additional current path in addition to the internal metal layer 120 of the substrate 100, thereby simplifying the current loop of the power module 1 and improving the electrical characteristics of the power module 1. Since the power module 1 according to an embodiment of the present disclosure forms an additional current path with the metal layer 300, the size of the substrate 100 may be reduced, thereby enabling miniaturization and reducing the manufacturing cost.

Referring to FIG. 2, the metal layer 300 may include, for example, a substrate counterpart 310 and a lead counterpart 320. The substrate counterpart 310 may be disposed to face the substrate 100. The substrate counterpart 310 may be embedded inside the molded portion 400. The lead counterpart 320 may protrude from an (e.g., one) end portion of the substrate counterpart 310 and at least a portion thereof may be exposed to the outside of the molded portion 400. The substrate counterpart 310 and the lead counterpart 320 may be provided as a single body. A width D1 of the lead counterpart 320 may be less than a width D2 of the substrate counterpart 310. At least a portion of the lead counterpart 320 may be exposed to the outside of the molded portion 400 and connected to an external power source.

The metal layer 300 may correspond to one of a positive terminal, a negative terminal, and an output terminal. The power lead 200 may form a current loop with the metal layer 300. For example, if the metal layer 300 is a positive terminal, the power lead 200 may include at least one negative terminal. If the metal layer 300 is a negative terminal, the power lead 200 may include at least one positive terminal. If the metal layer 300 is an output terminal, the power lead 200 may include both a positive terminal and a negative terminal.

The spacer 150 may connect the substrate counterpart 310 to the chip 140. When the metal layer 300 is connected to an upper surface of the chip 140 through the spacer 150, the current loop CL may be formed via the power lead 200, the substrate 100, the chip 140, the spacer 150, and the metal layer 300.

The molded portion 400 may form an outer portion of the power module 1. The molded portion 400 may be provided to surround at least a portion of the outer surface of the metal layer 300, the power lead 200, and the substrate 100. For example, the molded portion 400 may expose the external metal layer 130 of the substrate 100, such that an (e.g., one) end portion of the power lead 200 and an (e.g., one) end portion of the metal layer 300 are exposed external (e.g., to the molded portion 400). The chip 140 may be embedded in the molded portion 400. The molded portion 400 may be formed of, for example, an epoxy molding compound (EMC) or a silicone gel (Si gel).

Referring to FIG. 3, the metal layer 300 may not be connected to the upper surface of the chip 140 but may be connected to the substrate 100 through the spacer 150. The spacer 150 may support the metal layer 300 so that the metal layer 300 may be disposed above the substrate 100. The metal layer 300 may include the substrate counterpart 310 disposed to face the substrate 100 and embedded inside the molded portion 400 and the lead counterpart 320 protruding from an (e.g., one) end portion of the substrate counterpart 310 and at least partially exposed to the outside of the molded portion 400. The spacer 150 may electrically and physically connect the substrate counterpart 310 to the substrate 100. The substrate counterpart 310 may be connected to the chip 140 through a wire W. The power module 1 illustrated in FIG. 3 is substantially the same as the power module 1 illustrated in FIG. 1; however, the metal layer 300 is connected to the substrate 100 through the spacer 150 and the metal layer 300 and the chip 140 are connected using the wire W.

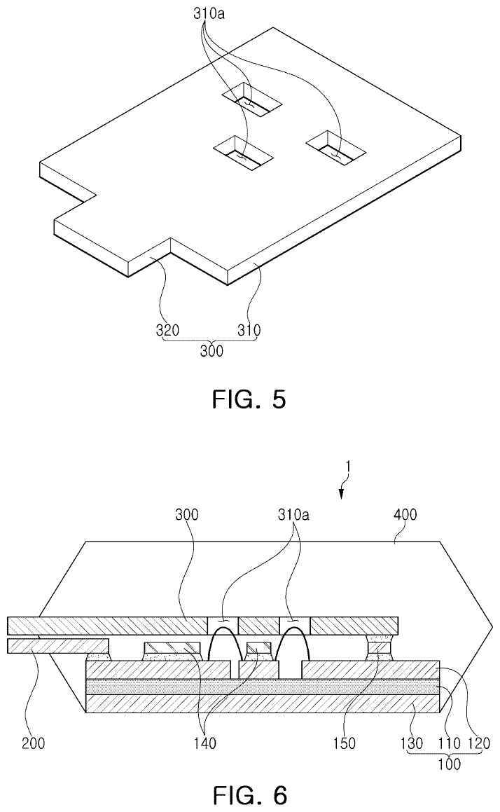

FIG. 4 is a schematic cross-sectional view of a power module according to another embodiment of the present disclosure, FIG. 5 is a schematic perspective view of a metal layer provided in a power module according to another embodiment of the present disclosure, and FIG. 6 is a schematic cross-sectional view of a power module according to another embodiment of the present disclosure.

Referring to FIG. 4, the power module 1 according to an embodiment of the present disclosure may include the substrate 100, the power lead 200, the metal layer 300, and the molded portion 400. The power module 1 according to an embodiment of the present disclosure illustrated in FIG. 4 is substantially the same as the power module illustrated in FIG. 1; however, the shape and connection configuration of the metal layer 300 are different. Therefore, a detailed description of the same components may be omitted and redisposed within at least a portion of the description herein.

Continuing with FIG. 4, the substrate 100 may include the insulating layer 110, the internal metal layer 120, and the external metal layer 130. At least one chip 140 may be mounted on the substrate 100. The chip 140 may be electrically connected to the internal metal layer 120 of the substrate 100. The chip 140 may convert DC power supplied through the power lead 200 into AC power. The chip 140 may be connected to the substrate 100 using the wire W. The chip 140 may be electrically connected to a circuit line formed on the internal metal layer 120 through the wire W. At least a portion of the wire W may be disposed in a through-hole 310a of the metal layer 300.

The power lead 200 may be connected to the substrate 100. The power lead 200 may be provided to supply power to the chip 140 mounted on the substrate 100 or to output power converted by the chip 140. An (e.g., one) end of the power lead 200 may be connected to the substrate 100 inside the molded portion 400 and another (e.g., the other) end thereof may be exposed to the outside of the molded portion 400.

The molded portion 400 may form an outer portion of the power module 1. The molded portion 400 may be provided to surround at least a portion of the outer surface of the substrate 100, the power lead 200, and the metal layer 300. For example, the molded portion 400 may expose the external metal layer 130 of the substrate 100, an (e.g., one) end portion of the power lead 200, and an (e.g., one) end portion of the metal layer 300 externally. The chip 140 may be embedded inside the molded portion 400.

The metal layer 300 may be spaced apart from the substrate 100. The metal layer 300 may be electrically connected to the chip 140 and the power lead 200 to form a current loop CL. The metal layer 300 may be provided with a conductive component, such as LTCC, PCB, or metal. The metal layer 300 may serve as an additional current path to improve the electrical characteristics of the power module 1. The metal layer 300 may have a (e.g., one) side connected to the chip 140. For example, the metal layer 300 may be connected to a (e.g., one) surface of the chip 140 that does not face the substrate 100. When the metal layer 300 is connected to the chip 140, the current loop CL may be formed via the power lead 200, the substrate 100, the chip 140, and the metal layer 300.

Referring to FIG. 5, the metal layer 300 may include the substrate counterpart 310 and the lead counterpart 320. The substrate counterpart 310 may be provided to face the substrate 100. The substrate counterpart 310 may be embedded inside the molded portion 400. The lead counterpart 320 may be provided to protrude from a (e.g., one) side of the substrate counterpart 310.

At least one through-hole 310a may be provided inside the substrate counterpart 310. The through-hole 310a may be provided to prevent contact between the wire W and the metal layer 300 during wire bonding of the chip 140. The through-hole 310a may prevent a short-circuit from occurring due to the metal layer 300 and the wire W coming into contact. The number, position, and shape of the through-holes 310a may be changed in accordance with the number, position, and/or the like of chips 140 mounted on the substrate 100. That is, the through-hole 310a may be changed to various shapes, such that the shape corresponds to a configuration that may prevent a short-circuit between the metal layer 300 and the wire W.

Referring to FIG. 6, the metal layer 300 may not be connected to the upper surface of the chip 140, but may be connected to the substrate 100 through the spacer 150. The spacer 150 may support the metal layer 300 so that the metal layer 300 may be disposed above the substrate 100. When the metal layer 300 is connected to the substrate 100 through the spacer 150, a current loop CL may be formed via the power lead 200, the substrate 100, the chip 140, the spacer 150, and the metal layer 300.

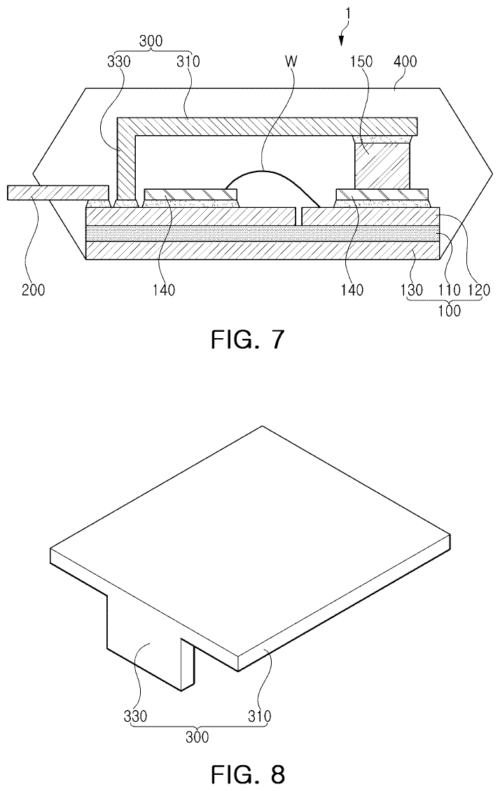

FIG. 7 is a schematic cross-sectional view of a power module according to another embodiment of the present disclosure, and FIG. 8 is a schematic perspective view of a metal layer provided in a power module according to another embodiment of the present disclosure.

Referring to FIG. 7, the power module 1 according to another embodiment of the present disclosure may include the substrate 100, the power lead 200, the metal layer 300, and the molded portion 400. The power module 1 illustrated in FIG. 7 is substantially the same as the power module illustrated in FIG. 1; however, the shape and connection configuration of the metal layer 300 are different. Therefore, a detailed description of the same components may be omitted and provided with at least a portion of the description herein.

The substrate 100 may include the insulating layer 110, the internal metal layer 120, and the external metal layer 130. At least one chip 140 may be mounted on the substrate 100. The chip 140 may be electrically connected to the internal metal layer 120 of the substrate 100. The chip 140 may be connected to the substrate 100 using the wire W. The chip 140 may convert DC power supplied through the power lead 200 into AC power.

The power lead 200 may be connected to the substrate 100. The power lead 200 may be provided to supply power to the chip 140 mounted on the substrate 100 or to output power converted by the chip 140. An (e.g., one) end of the power lead 200 may be connected to the substrate 100 inside the molded portion 400 and another (e.g., the other) end may be exposed to the outside of the molded portion 400.

The metal layer 300 may be spaced apart from the substrate 100. The metal layer 300 may be electrically connected to the chip 140 and the power lead 200 to form a current loop CL. The metal layer 300 may be provided with a conductive component, such as LTCC, PCB, or metal. The metal layer 300 may act as an additional current path, thereby improving the electrical characteristics of the power module 1. The spacer 150 may support the metal layer 300. For example, the spacer 150 may support the metal layer 300 by having an (e.g., one) end connected to the upper surface of the chip 140 and another (e.g., the other) end connected to the metal layer 300.

Referring to FIG. 8, the metal layer 300 may include the substrate counterpart 310 and a bent portion 330. The substrate counterpart 310 may be spaced apart from the substrate 100 and disposed to face the substrate 100. The bent portion 330 may be bent toward the substrate 100 from an (e.g., one) end portion of the substrate counterpart 310. The metal layer 300 may be formed in an overall ‘L’ shape. The bent portion 330 may be electrically connected to the substrate 100 at the bent end. The bent portion 330 may be electrically connected to the power lead 200 via the substrate 100. At this time, it is also possible to (e.g., directly) connect the bent portion 330 to the power lead 200. The substrate counterpart 310 may be connected to the chip 140 via the spacer 150. An (e.g., one) end of the spacer 150 may be connected to the upper surface of the chip 140 and another (e.g., the other) end may be connected to the lower surface of the substrate counterpart 310. However, the spacer 150 may be omitted. In other words, it is also possible to (e.g., directly) connect the substrate counterpart 310 to a (e.g., one) surface of the chip 140 that does not face the substrate 100, that is, the upper surface. The substrate counterpart 310 may be electrically connected to the chip 140. In the embodiment illustrated in FIGS. 7 and 8, the metal layer 300 may not be exposed to the outside of the molded portion 400 but may be embedded inside the molded portion 400.

In the embodiment illustrated in FIGS. 7 and 8, the metal layer 300 may have the same potential as the power lead 200. In other words, the power lead 200 may include a positive terminal, a negative terminal, and an output terminal, and the metal layer 300 may form an extension path of one of the positive terminal, the negative terminal, or the output terminal of the power lead 200. Accordingly, the metal layer 300 may have the same potential as that of one of the positive terminal, the negative terminal, or the output terminal.

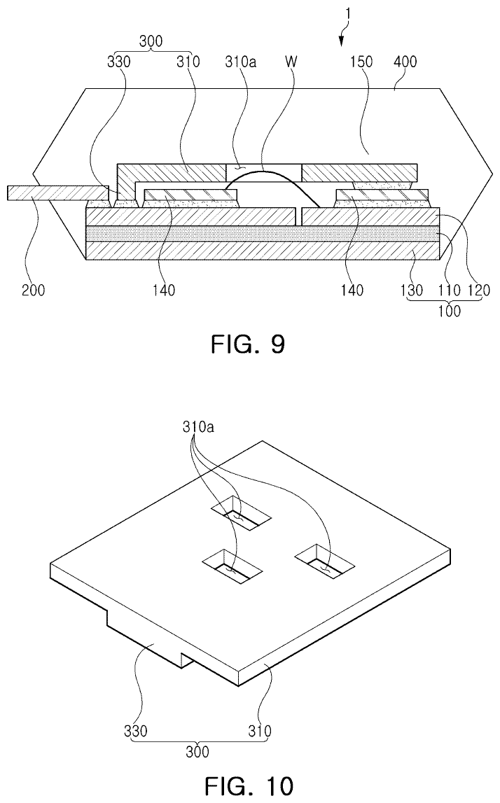

FIG. 9 is a schematic cross-sectional view of a power module according to another embodiment of the present disclosure, and FIG. 10 is a schematic perspective view of a metal layer provided in a power module according to another embodiment of the present disclosure.

Referring to FIG. 9, the power module 1 according to another embodiment of the present disclosure may include the substrate 100, the power lead 200, the metal layer 300, and the molded portion 400. The power module 1 according to an embodiment of the present disclosure illustrated in FIG. 9 is substantially the same as the power module illustrated in FIG. 1; however, the shape and connection configuration of the metal layer 300 is different. Therefore, a detailed description of the same components may be omitted and provided with at least a portion of the description herein.

The substrate 100 may include the insulating layer 110, the internal metal layer 120, and the external metal layer 130. At least one chip 140 may be mounted on the substrate 100. The chip 140 may be electrically connected to the internal metal layer 120 of the substrate 100. The chip 140 may convert DC power supplied through the power lead 200 into AC power. The chip 140 may be connected to the substrate 100 using the wire W. The chip 140 may be electrically connected to a circuit line formed on the internal metal layer 120 through the wire W. At least a portion of the wire W may be disposed in the through-hole 310a of the metal layer 300.

The power lead 200 may be connected to the substrate 100. The power lead 200 may be provided to supply power to the chip 140 mounted on the substrate 100 or to output power converted by the chip 140. An (e.g., one) end of the power lead 200 may be connected to the substrate 100 inside the molded portion 400 and another (e.g., the other) end may be exposed to the outside of the molded portion 400.

The metal layer 300 may be spaced apart from the substrate 100. The metal layer 300 may be embedded inside the molded portion 400. The metal layer 300 may be electrically connected to the chip 140 and the power lead 200 to form a current loop CL. The metal layer 300 may be provided with a conductive component, such as LTCC, PCB, or metal. The metal layer 300 may serve as an additional current path to improve the electrical characteristics of the power module 1. A (e.g., one) side of the metal layer 300 may be connected to the chip 140. For example, the metal layer 300 may be connected to a (e.g., one) surface of the chip 140 that does not face the substrate 100.

Referring to FIG. 10, the metal layer 300 may include the substrate counterpart 310 and the bent portion 330. The substrate counterpart 310 may be provided to face the substrate 100. The substrate counterpart 310 may be connected to the upper surface of the chip 140. The bent portion 330 may be bent toward the substrate 100 from one end portion of the substrate counterpart 310. The metal layer 300 may be provided in an overall ‘L’ shape. The bent end of the bent portion 330 may be electrically connected to the substrate 100. The bent portion 330 may be electrically connected to the power lead 200 via the substrate 100. At this time, it is also possible to (e.g., directly) connect the bent portion 330 to the power lead 200.

At least one through-hole 310a may be provided inside the substrate counterpart 310. The through-hole 310a may be provided to prevent contact between the wire W and the metal layer 300 during wire bonding of the chip 140. The through-hole 310a may prevent a short-circuit from occurring due to contact between the metal layer 300 and the wire W. The number, position, and shape of the through-hole 310a may be changed in accordance with the number, position, and/or the like of chips 140 mounted on the substrate 100. That is, the through-hole 310a may be changed to various shapes, such that the shape corresponds to a configuration that may prevent a short-circuit between the metal layer 300 and the wire W.

In the embodiment illustrated in FIGS. 9 and 10, the metal layer 300 may have the same potential as that of the power lead 200. In other words, the power lead 200 may include a positive terminal, a negative terminal, and an output terminal, and the metal layer 300 may form an extension path of one of the positive terminal, the negative terminal, or the output terminal of the power lead 200. Accordingly, the metal layer 300 may have the same potential as that of one of the positive terminal, the negative terminal, or the output terminal.

The power module according to embodiments of the present disclosure may improve electrical characteristics.

The power module according to embodiments of the present disclosure may provide for miniaturization.

The power module according to embodiments of the present disclosure may reduce the manufacturing cost.

While embodiments have been shown and described above, it will be apparent to those skilled in the art that modifications and variations may be made without departing from the scope of the present disclosure as provided by the claims.

What is claimed is:

1. A power module comprising:
a substrate with at least one chip mounted thereon;
a power lead connected to the substrate to supply power to the chip or output power converted by the chip;
a metal layer electrically connected to the chip and the power lead to form a current loop; and
a molded portion surrounding at least a portion of an outer surface of the substrate, the power lead, and the metal layer to embed the chip therein.

2. The power module of claim 1, wherein the chip is provided as a plurality of chips, and at least one of the plurality of chips is electrically connected to the metal layer.

3. The power module of claim 1, wherein the power lead includes at least one negative terminal when the metal layer is a positive terminal, includes at least one positive terminal when the metal layer is a negative terminal, and includes both a positive terminal and a negative terminal when the metal layer is an output terminal.

4. The power module of claim 1, wherein the power lead includes a positive terminal, a negative terminal, and an output terminal, and the metal layer forms an extension path of at least one of the positive terminal, the negative terminal, or the output terminal.

5. The power module of claim 1, wherein
the metal layer includes:
a substrate counterpart disposed to face the substrate and is embedded inside the molded portion; and
a lead counterpart protruding from an end portion of the substrate counterpart and at least partially exposed to an outside of the molded portion.

6. The power module of claim 5, wherein a spacer is provided to connect the substrate counterpart to the chip, and the current loop is formed with the power lead, the substrate, the chip, the spacer, and the metal layer.

7. The power module of claim 5, wherein a spacer is provided to connect the substrate counterpart to the substrate, and the substrate counterpart is connected to the chip by a wire.

8. The power module of claim 1, wherein
the metal layer includes:
a substrate counterpart disposed to face the substrate; and
a bent portion bent from an end portion of the substrate counterpart and connected to an end portion of the substrate,
wherein the metal layer is embedded inside the molded portion.

9. The power module of claim 8, wherein a spacer is provided to connect the substrate counterpart to the chip.

10. The power module of claim 8, wherein the substrate counterpart is connected to a surface of the chip that does not face the substrate.

11. A power module comprising:
a substrate with a chip mounted thereon;
a power lead connected to the substrate to supply power to the chip;
a metal layer electrically connected to the chip and the power lead to form a current loop, wherein the metal layer has at least one through-hole formed therein; and
a molded portion provided to surround at least a portion of an outer surface of the substrate, the power lead, and the metal layer to embed the chip within the molded portion.

12. The power module of claim 11, wherein the chip is connected to the substrate using a wire, and at least a portion of the wire is disposed in the through-hole.

13. The power module of claim 12, wherein a spacer is provided to connect the metal layer to the substrate.

14. The power module of claim 12, wherein the metal layer is connected to a surface of the chip that does not face the substrate.

15. The power module of claim 12, wherein
the metal layer includes:
a substrate counterpart disposed to face the substrate, having the through-hole formed inside the substrate counterpart, and embedded inside the molded portion; and
a lead counterpart protruding from an end portion of the substrate counterpart and at least partially exposed to an outside of the molded portion.

16. The power module of claim 12, wherein
the metal layer includes:
a substrate counterpart disposed to face the substrate, having the through-hole formed inside the substrate counterpart, and connected to a surface of the chip that does not face the substrate; and
a bent portion bent from an end portion of the substrate counterpart and having an end portion connected to the substrate,
wherein the metal layer is embedded inside the molded portion.

17. A power module comprising:
a substrate with at least one chip mounted thereon,
wherein the substrate includes an insulating layer,
an internal metal layer provided on a surface of the insulating layer, and
an external metal layer provided on another surface of the insulating layer;
a power lead connected to the substrate to supply power to the chip or output power converted by the chip;
a metal layer electrically connected to the chip and the power lead to form a current loop; and
a molded portion surrounding at least a portion of an outer surface of the substrate, the power lead, and the metal layer to embed the chip within the molded portion, and
wherein at least a portion of the external metal layer is exposed to an outside of the molded portion.

18. The power module of claim 17, wherein the chip is connected to the substrate using a wire.

19. The power module of claim 17, wherein the metal layer 300 is provided with a conductive component, wherein the conductive component is LTCC, PCB, or metal.

20. The power module of claim 17, wherein the chip is provided as a plurality of chips, and at least one of the plurality of chips is electrically connected to the metal layer.
